(19) United States
(12) Patent Application Publication
(10) Pub. No.: US 2016/0006411 A1
(43) Pub. Date: Jan. 7, 2016

(54) TUNING FORK AND ELECTRONIC DEVICE USING THE SAME

(71) Applicant: SAMSUNG ELECTRO-MECHANICS CO., LTD., Suwon-si (KR)

(72) Inventors: Won HAN, Osan-si (KR); Sung Wook KIM, Suwon-si (KR)

(73) Assignee: SAMSUNG ELECTRO-MECHANICS CO., LTD., Suwon-si (KR)

(21) Appl. No.: 14/789,417

(22) Filed: Jul. 1, 2015

(30) Foreign Application Priority Data
Jul. 7, 2014 (KR) 10-2014-0084346

(51) Int. Cl. H03H 9/05; H03H 9/21

(52) U.S. Cl. CPC H03H 9/0595; H03H 9/21

(57) ABSTRACT

A tuning fork may include a vibrating part in which a plurality of vibrating members having vibrating heads which are formed at free ends of tines are connected at both sides of a connection member, and a support part in which the vibrating part is coupled with the connection member. The vibrating part may include two tines formed in parallel with each other and the connection member formed in a direction to the free end of the tines from fixed ends of the tines, being spaced apart from each other by a predetermined distance, and connecting between the two tines.

This application claims the foreign priority benefit under 35 U.S.C. Section 119 of Korean Patent Application Serial No. 10-2014-0084346, entitled “Tuning Fork And Electronics Device Using The Same” filed on Jul. 7, 2014, which is hereby incorporated by reference in its entirety into this application.

### BACKGROUND

1. Technical Field

Some embodiments of the present disclosure relates to a tuning fork having a central beam structure and an electronic device using the same.

2. Description of the Related Art

Unless otherwise indicated herein, the materials described in this section are not prior art to the claims herein and are not admitted to be prior art by inclusion in this section.

A tuning fork may be, for example, but not limited to, a part of mobile devices which is configured of a quartz X-tal chip having a tuning fork shape. For instance, the tuning fork may generate an eigen frequency of 32.768 kHz using a piezoelectric effect of quartz and be used as a timing clock.

Recently, with a rapid growth of a smart phone and a tablet PC capable of implementing various functions, a demand for the tuning fork tends to be increased.

In particular, as an electronic device is increasingly miniaturized recently, miniaturization of the tuning fork may be needed.

The tuning fork may have two tines which are connected to a base, grooves which are formed inside the tines, and an electrode which may oscillate crystal therearound.

A main performance of the tuning fork may be determined based on a numerical value of equivalent series resistance (ESR). For example, when the ESR value is low, a crystal resonator may be oscillated well and power consumption may be reduced.

The ESR is determined by piezo-electric charge and damping which are generated at the time of deformation of a piezoelectric substance. When the piezo-electric charge is high or the damping is low, the low ESR may be achieved.

The piezo-electric charge may be affected by a distance between a positive electrode and a negative electrode. As the inter-electrode distance is small, the ESR value may be low. In the structure of the tuning fork, the inter-electrode distance may be determined by patterning and etching processes of the body and the groove, and therefore there may be a limitation in reducing the distance between the electrodes.

On the other hand, when the damping is designed to be small, the ESR may be low and thus the efficiency of the tuning fork may be increased.

The damping may be affected by air, a material, a structure, and the like. If the tuning fork is used in a vacuum package state and is made using the quartz crystal, the damping may be affected by the structure. By the way, the damping influence due to the structure may be possible when a loss of vibration is reduced.

However, with the recent tendency to miniaturize a package, there is a need to implement the low ESR while reducing the overall size of the tuning fork. To reduce the overall size of the tuning fork, there is a need to reduce a length of the tine. Therefore, many researches to reduce the loss of vibration have been conducted.

### SUMMARY

Some embodiments of the present disclosure may provide a tuning fork capable of minimizing a loss of vibration without increasing a size of the tuning fork.

According to an exemplary embodiment of the present disclosure, a tuning fork may include a vibrating part in which a plurality of vibrating members having vibrating heads which are formed at free ends of tines are connected at both sides of a connection member; and a support part in which the vibrating part is coupled with the connection member.

The vibrating part may include a plurality of parallel tines and the connection member. The connection member may be adjacently positioned to a fixed end of the tine in a direction to the free end from the fixed end and connect between the plurality of tines.

The vibrating part may include two or more vibrating members formed in parallel with each other and the connection member formed to be spaced apart from lower ends of the vibrating members by a predetermined distance to connect between the vibrating members so as to transfer vibration generated from the vibrating part to a support part, thereby blocking a loss of vibration.

The vibrating part of the tuning fork may have an H shape. A support part may include a base, a central member connecting a central portion of the base to a central portion of the connection member, and support arms vertically formed at both ends of the base in parallel with the tines to effectively control the vibration generated from the vibrating part.

A connection portion between the connection member and the tine may be provided with a curved chamfer, for example, but not limited to, to mitigate a concentration of stress due to the vibration generated from the vibrating part. The chamfer may be formed at an upper or a lower portion of the connection member or both upper and lower portions thereof.

### BRIEF DESCRIPTION OF THE DRAWINGS

FIG. 1 is a perspective view of a tuning fork according to an exemplary embodiment of the present disclosure.

FIG. 2 is a plan view of a tuning fork according to an exemplary embodiment of the present disclosure.

FIG. 3A is a plan view illustrating a distribution of stress applied when a tuning fork vibrates according to the related art.

FIG. 3B is a plan view illustrating a distribution of stress applied at the time of vibrating a tuning fork according to an exemplary embodiment of the present disclosure.

FIG. 4 is a plan view of a tuning fork according to a second exemplary embodiment of the present disclosure.

FIG. 5 is a plan view of a tuning fork according to a third exemplary embodiment of the present disclosure.

FIG. 6 is a plan view of a tuning fork according to a fourth exemplary embodiment of the present disclosure.

FIG. 7A is a plan view illustrating a quartz etching simulation result in the case in which a tilt angle of a chamfer is 35°, and FIG. 7B is a plan view illustrating a quartz etching simulation result in the case in which a tilt angle of a chamfer is 55 to 60°

### DESCRIPTION OF THE PREFERRED EMBODIMENTS

Terms used in the present disclosure are for explaining exemplary embodiments rather than limiting the present invention. Unless explicitly described to the contrary, a singular form includes a plural form in the present disclosure. Also, used herein, the word “comprise” and/or “comprising” will be understood to imply the inclusion of stated constituents, steps, numerals, operations and/or elements but not the exclusion of any other constituents, steps, operations and/or elements.

The above and other objects, features and advantages of the present invention will be more clearly understood from the following detailed description taken in conjunction with the accompanying drawings. In the disclosure, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the specification, the terms “first”, “second”, and so on are used to distinguish one element from another element, and the elements are not defined by the above terms.

Hereinafter, exemplary embodiments of the present disclosure will be described in detail with reference to the accompanying drawings.

Some of the present disclosure may generally relate to a tuning fork having a connection member connecting a plurality of vibrating members and a central member connecting the connection member to a base.

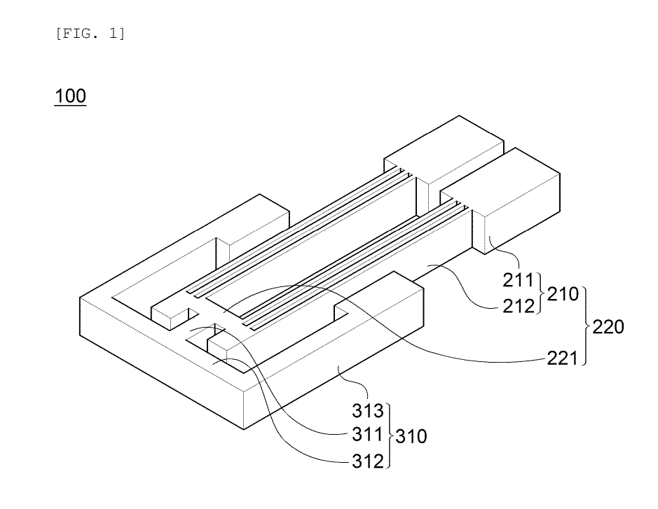

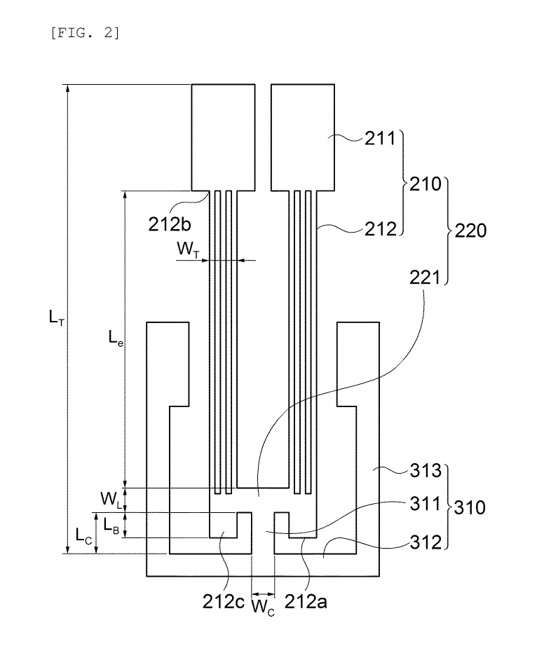

FIG. 1 is a perspective view of a tuning fork according to first exemplary embodiment of the present disclosure, and FIG. 2 is a plan view of the tuning fork according to the first exemplary embodiment of the present disclosure. Efficiency of the tuning fork may be increased by deforming a shape of the tuning fork. An electrode may be generally included in the tuning fork, but not illustrated in the drawings.

A tuning fork 100 according to an exemplary embodiment of the present disclosure may have a structure including a vibrating part 220 and a support part 310 as illustrated in FIGS. 1 and 2.

In this configuration, a material of the tuning fork 100 is not particularly limited, but, for example, quartz or a piezoelectric material may be used.

The vibrating part 220 may include one or a plurality of vibrating members 210 and a connection member 221. For instance, in the embodiment of the present disclosure, the vibrating member 210 may include two tines or vibrating arms 212 and two vibrating heads 211. However, the vibrating member 210 may comprise more than two tines 212 and/or vibrating heads 211.

The plurality of vibrating members 210 may be formed in parallel with each other and may be connected to each other by the connection member 221.

The vibrating member 210 may include the tine 212 and the vibrating head 211 formed at a free end 212b of the tine 212. The vibrating head 211 may serve to amplify vibration generated from the tine 212. In this case, one end of the plurality of tines 211 in a direction of the connection member 221 may be defined as a fixed end 212a, and another end of the plurality of tines 212 in a direction of the vibrating head 211 may be defined as the free end 212b. Further, a portion protruding from the tine 212 to the fixed end 212a is defined as a protrusion 212c.

The connection member 221 may be formed to be biased to the fixed end 212a of the tine 212 to connect between the plurality of vibrating members 210. The connection member 221 may be formed to be spaced from the fixed end 212a of the tine 212 by a predetermined distance LB.

The distance LB from the fixed end 212a of the tine 212 to the connection member 221 may be, for example, but not limited to, 0.02 to 0.2 times of a total length LT of the vibrating member 210.

However, the present disclosure is not limited to this range. The distance LB from the fixed end 212a of the tine 212 to the connection member 221 may be below 0.02 times of the length LT of the vibrating member 210. However, this distance may not help in miniaturizing the size of the package which may be reduced by forming the connection member 221 to be spaced apart from the fixed end 212a of the tine 212. Additionally, the distance LB may be formed 0.2 times or more of the length LT. However, a length Le of an effective tine having relatively excellent vibration efficiency may be reduced and thus it may be difficult to be implemented at 32.768 kHz which may be an eigen frequency of quartz crystal at a small package size.

For example, when the total length LT of the vibrating member 210 is 1 to 1.2 mm, the width W_{T} of the tine 212 is 55 to 65 μm, and the length of the distance LB from the fixed end 212a of the tine 212 to the connection member 221 is 30 to 60 μm, the tuning fork 100 may satisfy a frequency of 32 to 32.768 kHz and may have an ESR value of 90 kΩ, in a 1610 (1.6 mm in length×1.0 mm in width) package size.

When the connection member 221 is formed at the fixed end 212a of the tine 212 without being spaced apart from the fixed end 212a of the tine 212 by the predetermined distance, the overall shape of the vibrating part 220 may be formed to be similar to a U shape. In this case, to prevent the overall size of the tuning fork package from increasing, the length of the vibrating member 210 may need to be reduced. When the length of the vibrating member 210 is not reduced, the overall size of the tuning fork package may be increased or the vibration efficiency may be reduced due to the reduction in the length of the vibrating member 210 in the tuning fork package having the same size.

As in the exemplary embodiment of the present disclosure, when the plurality of vibrating members 210 are connected to each other by the connection member 221 formed at a distance spaced apart from the fixed end 212a of the tine 212, the vibrating part 220 and the support part 310 may be spaced apart from each other without reducing the total length of the vibrating member 210 by the central member 311 of the support part 310 to be described below. The vibrating part 220 and the support part 310 may be spaced apart from each other to prevent vibration stress, generated from the vibrating part 220, from being transferred to the support part 310, thereby minimizing the reduction in vibration efficiency due to the stress.

For example, but not limited to, a width W_{L} of the connection member 221 may be 0.5 to 1.5 times of the width W_{T} of the tine 212.

However, the present disclosure is not limited to this range. The width W_{L} of the connection member 221 may be below 0.5 times of the width W_{T} of the tine 212. However, the connection member 221 may be likely to be damaged due to an external impact during the process and thus a manufacturing yield thereof may be reduced. Additionally, the width W_{L} of the connection member 221 may be 1.5 times or more of the width W_{T} of the tine 212. However, the connection member 221 may occupy a large space in the tuning fork package and thus the space efficiency may reduced, such that it may be difficult to implement a subminiature package.

For example, the shape of the vibrating part 220 may be generally an H shape, but not limited thereto.

The vibrating part 220 may be connected to the support part 310 through the central member 311. The support part 310 may include the central member 311, a base 312, and a support arm 313.

The central member 311 may be formed toward the central side of the connection member 221 of the vibrating part 220 from the central portion of the base 312 parallel with the connection member 221. Both ends of the base 312 may be provided with the plurality of support arms 313 formed in a parallel direction with the vibrating member 210.

The support arm 313 may serve to block external stress. The external stress generated due to a change in external force or impact and temperature may be introduced into the tuning fork 100 through the package to hinder the vibration of the tine 212 or lead to the change in frequency. The support arm 313 may block the influence to make the tine 212 constantly vibrate at a specific frequency even in the case that the external stress is generated.

An upper end of the support arm 313 may be formed to have a wider width than a lower end of the support arm 313 to be bonded to a pad of the package.

The central member 311 may be formed to connect the center of the connecting member 221 of the vibrating part 220 to the center of the base 312 of the support part 310. The vibrating part 220 and the support part 310 may be spaced apart from each other by a length L_{C} of the central member 311.

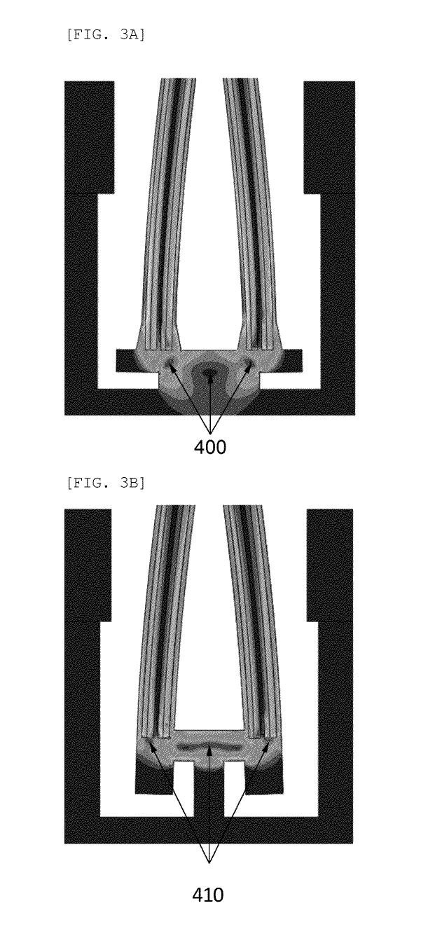

FIG. 3A is a plan view illustrating a stress distribution at the time of vibrating a tuning fork according to the related art, and FIG. 3B is a plan view illustrating a stress distribution at the time of vibrating the tuning fork 100 according to the exemplary embodiment of the present disclosure.

Referring to FIG. 3A, in the case of the tuning fork according to the related art, when the plurality of vibrating members are vibrated by being coupled with each other, stress nodes 400 on which the stress is concentrated may deviate from the vibrating part up to the base. By doing so, vibration energy may be transferred to an outside of the vibrating part and the ESR may be increased with an increase of structural damping due to dissipation of vibration energy. However, in the case of the tuning fork 100 according to the exemplary embodiment of the present disclosure, the stress nodes 410 on which the stress is concentrated may be formed in the connection member 221 within the vibrating part 220, and as a result the vibration energy is not transferred to the outside of the vibrating part 220 to suppress the increase in the structural damping, thereby minimizing the increase in the ESR.

The length and the width of the base 312 and the tine 212 may be appropriately adjusted depending on the overall size and shape of the tuning fork package.

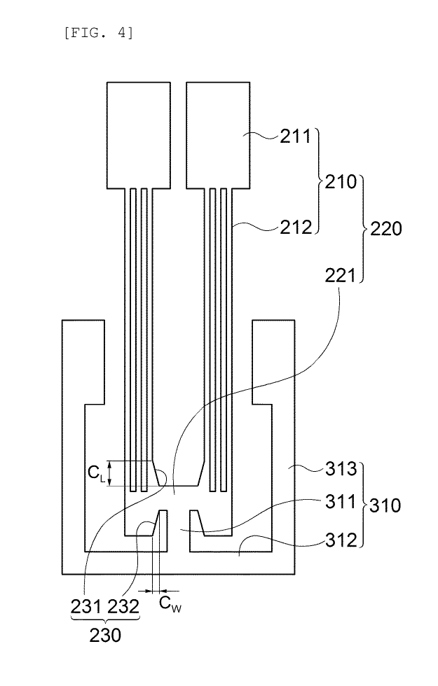

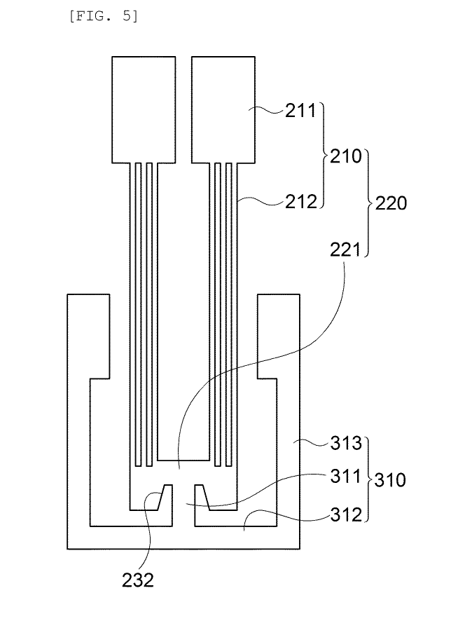

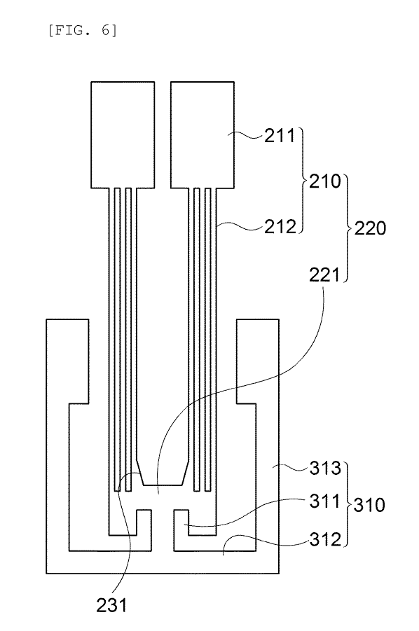

FIG. 4 is a plan view of a tuning fork according to a second exemplary embodiment of the present disclosure, FIG. 5 is a plan view of a tuning fork according to a third exemplary embodiment of the present disclosure, and FIG. 6 is a plan view of a tuning fork according to a fourth exemplary embodiment of the present disclosure.

According to the exemplary embodiment of the present disclosure, a connection portion between the connection member 221 and the tine 212 is provided with a curved chamfer 230 to be able to mitigate the concentration of stress. The chamfers 230 may be formed at both of an upper end and a lower end of the connection member 221 as illustrated in FIG. 4. Alternatively, as illustrated in FIG. 5, the chamfers 230 may be formed only at the lower end of the connection member 221 or as illustrated in FIG. 6, may be formed only at the upper end of the connection member 221.

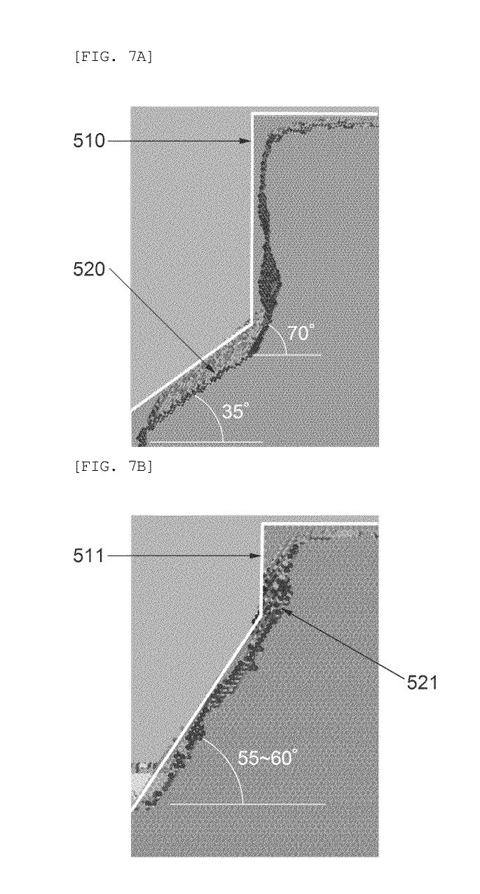

FIG. 7A is a plan view illustrating a quartz etching simulation result in the case in which a tilt angle of the chamfer is 35°, and FIG. 7B is a plan view illustrating the quartz etching simulation result in the case in which the tilt angle of the chamfer is 55 to 60°.

As illustrated, when the shape of the chamfer is processed, a processing shape profile may be different depending on a tilt angle of a mask of the chamfer due to etching anisotropy of the quartz.

As illustrated in FIG. 7A, when the tilt angle of a mask profile 510 of the chamfer is 35°, a processing shape profile 520 is formed to have two angles of 35° and 70° and thus may be manufactured by an unintended result in the design. However, as illustrated in FIG. 7B, when the tilt angle of the mask profile 511 of the chamfer ranges from 55° to 60°, the processing shape profile 521 may be formed, having one angle.

For example, when the tilt angle of the mask profile 511 of the chamfer is 55°, a ratio C_{L}/C_{W} of a chamfer length C_{L} to a chamfer width C_{W} may be 1.43, and when the tilt angle of the chamfer is 60°, the ratio C_{L}/C_{W} of the chamfer length C_{L} to the chamfer width C_{W} may be 1.73. Tt is preferable that the ratio C_{L}/C_{W} of the chamfer length C_{L} to the chamfer width C_{W} may be 1.43 to 1.73, but not limited thereto.

According to the exemplary embodiments of the present disclosure, the vibrating part 220 generating vibration and the support part 310 are spaced apart from each other by introducing the connection member 221 connecting the vibrating members 210 and the central member 311 to make the stress due to the vibration generated from the vibrating part 220 stay in the vibration part, thereby improving vibration efficiency of the tuning fork 100.

Further, it is possible to provide the tuning fork 100 having the structure of the connection member 221 formed to be spaced apart from the end of the vibrating member 210 by a predetermined distance to reduce the overall size of the package of the tuning fork 100 while separating the vibrating part 220 and the support part 310 from each other.

The present invention has been described in connection with what is presently considered to be practical exemplary embodiments. In addition, the above-mentioned description discloses only the exemplary embodiments of the present invention. Therefore, it is to be appreciated that modifications and alterations may be made by those skilled in the art without departing from the scope of the present invention disclosed in the present specification and an equivalent thereof. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed exemplary embodiments. It is to be understood that other exemplary embodiments are also included within the spirit and scope of the appended claims.

What is claimed is:

1. A tuning fork, comprising:
a vibrating part comprising a plurality of vibrating members having vibrating heads which are formed at free ends of tines, the vibrating members connected at both sides of a connection member; and
a support part coupled with the connection member.

2. The tuning fork according to claim 1, wherein the vibrating part includes:
the parallel tines having the free ends and fixed ends; and
the connection member adjacently positioned to the fixed ends of the tines and connecting between the tines.

3. The tuning fork according to claim 1, wherein the vibrating part has an H shape.

4. The tuning fork according to claim 1, wherein the support part includes a base, a central member connecting a central portion of the base to a central portion of the connection member, and support arms formed at both ends of the base in parallel with the tines.

5. The tuning fork according to claim 1, wherein a distance from the fixed ends of the tines to the connection member is 0.02 to 0.2 times of a length of the vibrating members.

6. The tuning fork according to claim 1, wherein a width of the connection member is 0.5 to 1.5 times of a width of the tines.

7. The tuning fork according to claim 1, wherein a curved chamfer is formed between the connection member and the tines.

8. The tuning fork according to claim 7, wherein the chamfer is formed at an upper portion of the connection member.

9. The tuning fork according to claim 7, wherein the chamfer is formed at a lower portion of the connection member.

10. The tuning fork according to claim 7, wherein the chamfer is formed at upper and lower portions of the connection member.

11. The tuning fork according to claim 7, wherein the chamfer is formed so that a ratio of a chamfer length to a chamfer width is 1.43 to 1.73.

12. An electronic device including the tuning fork of claim 1.

13. A tuning fork, comprising:
a connection member;
tines connected to both sides of the connection member, each of the tines having one end provided with a protrusion and an other end provided with a vibrating head;
a central member formed to extend in parallel with the protrusion and be orthogonal to the connection member; and
a base formed to extend in parallel with the connection member and be orthogonal to the central member.

14. The tuning fork according to claim 13, wherein both sides of the base are provided with support arms extending in parallel with the tines.

15. A tuning fork, comprising:
a plurality of tines;
a connection member connecting between the tines so as to be spaced apart from each other and comprising a protrusion at one end of the tines;
a central member formed to extend in parallel with the protrusion and be orthogonal to the connection member; and
a base formed to extend in parallel with the connection member and be orthogonal to the central member.

16. The tuning fork according to claim 15, wherein the tines have an other end which is a free end and is provided with a vibrating head.

17. The tuning fork according to claim 15, wherein the central member extends in a direction in which the protrusion is protruded from the connection member.

18. The tuning fork according to claim 15, wherein the tines provided with the protrusion, the connection member connecting between the tines, and vibrating heads provided at the tines configure a vibrating part.

19. The tuning fork according to claim 18, wherein the central member connected to the vibrating part and the base orthogonal to the central member configure a support part, and
wherein the support part comprises support arms extending from both ends of the base toward the tines.
